(19) United States
(12) Patent Application Publication
(10) Pub. No.: US 2021/0325724 A1
(43) Pub. Date: Oct. 21, 2021

(54) COLOR PHOTORESIST, COLOR FILTER, AND MANUFACTURING METHOD THEREOF

(71) Applicant: TCL China Star Optoelectronics Technology Co., Ltd., Shenzhen (CN)

(72) Inventor: Lin AI, Shenzhen (CN)

(73) Assignee: TCL China Star Optoelectronics Technology Co., Ltd., Shenzhen (CN)

(21) Appl. No.: 16/627,356

(22) PCT Filed: Dec. 20, 2019
(86) PCT No.: PCT/CN2019/126878

§ 371 Date: Dec. 30, 2019

(30) Foreign Application Priority Data
Dec. 12, 2019 (CN) 201911271597.2

(51) Int. Cl. G02F 1/1335; G03F 7/00

(52) U.S. Cl. CPC G02F 1/133516; G03F 7/0007; G02F 1/133512

(57) ABSTRACT

A color photoresist comprises a curable resin, a polyfunctional monomer, an initiator, a solvent, a colorant, and an additive, wherein the additive is a non-metal catalyst catalyzing a cross-coupling photoreaction to be performed among compounds having a carbon-carbon single bond, compounds having a carbon-oxygen single bond, and compounds having a carbon-nitrogen single bond under ultraviolet light. The present disclosure further provides a color filter manufactured by the above color photoresist and a manufacturing method thereof.

### FIELD OF INVENTION

The present disclosure relates to the field of display technologies, and more particularly, to a color photoresist, a color filter, and a manufacturing method thereof.

### BACKGROUND OF INVENTION

Liquid crystal displays are the most widely used products in current market, and mainly comprise three components: color filter substrates, liquid crystals, and array substrates. RGB color photoresists on the color filter substrate respectively correspond to three sub-pixels on the array substrate, and the three sub-pixels form a pixel. The color display of liquid crystal displays is achieved mainly by RGB three color pixels on the color filter substrate. RGB three color pixels are formed by three different photoresists of RGB forming a film having a desired pattern structure to help display the colors.

Currently, a silicon nitride support substrate used to manufacture a color filter will be subjected to pre-cleaning processes, such as extreme ultraviolet radiation and water washing, which causes hydroxyl groups are added on a surface of the support substrate and hydrophilicity of the support substrate is enhanced, thereby making color photoresists disposed on the support substrate having poor adhesion and stripping phenomenon. If the pre-cleaning processes, such as extreme ultraviolet radiation and water washing, are omitted, the problem of color photoresist residues easily occurs in post processes. Current improving methods have two aspects. One aspect is that adjusting acid values of polymers covering the periphery of dye crystal particles which display the color of the color photoresist or adjusting functionality of monomers to improve adhesion, but it will affect other related properties in the processes, and need to reevaluate optimized components and proportions. The other aspect is that changing the dosage of additives, such as siloxane, which have a strong interaction force with a silicon nitride support substrate to improve adhesion, but these small organic-inorganic hybrid molecules will easily produce sublimating materials when heated in the pre-bake process due to poor heat resistance, which has post-processing and equipment maintenance problems for commercial production.

In summary, current color photoresists, color filters, and manufacturing method thereof have stripping phenomenon because hydroxyl groups are added on a surface of the support substrate and then hydrophilicity of the support substrate is enhanced after the support substrate is subjected to extreme ultraviolet radiation and water washing, thereby making color photoresists disposed on the support substrate having poor adhesion.

Technical problem: current color photoresists, color filters, and manufacturing method thereof have stripping phenomenon because hydroxyl groups are added on a surface of the support substrate and hydrophilicity of the support substrate is enhanced after the support substrate is subjected to extreme ultraviolet radiation and water washing, thereby making color photoresists disposed on the support substrate having poor adhesion a silicon nitride support substrate used to manufacture a color filter will be subjected to pre-cleaning processes, such as extreme ultraviolet radiation and water washing, which causes hydroxyl groups are added on a surface of the support substrate and hydrophilicity of the support substrate is enhanced, thereby making color photoresists disposed on the support substrate having poor adhesion and stripping phenomenon.

### SUMMARY OF INVENTION

In a first aspect, an embodiment of the present disclosure provides a color photoresist. The color photoresist comprises a curable resin, a polyfunctional monomer, an initiator, a solvent, a colorant, and an additive;

wherein the additive is a non-metal catalyst catalyzing a cross-coupling photoreaction to be performed among compounds having a carbon-carbon single bond, compounds having a carbon-oxygen single bond, and compounds having a carbon-nitrogen single bond under ultraviolet light.

In the color photoresist, wherein a mass percentage of the non-metal catalyst in the color photoresist ranges from 0.1% to 0.2%, and the non-metal catalyst is trifluoroacetic acid.

In the color photoresist, wherein a mass percentage of the curable resin in the color photoresist ranges from 5% to 8%, a mass percentage of the polyfunctional monomer in the color photoresist ranges from 5% to 8%, a mass percentage of the initiator in the color photoresist ranges from 0.2% to 0.6%, a mass percentage of the solvent in the color photoresist ranges from 70% to 80%, and a mass percentage of the colorant in the color photoresist ranges from 10% to 16%.

In the color photoresist, wherein the curable resin comprises an acrylic resin, the polyfunctional monomer comprises polyhydroxyl acrylate, the initiator comprises an acetophenone derivative, the solvent comprises propylene glycol methyl ether acetate, and the colorant is at least one selected from the group consisting of red benzimidazolone derivative color particles, green phthalocyanine green derivative color particles, blue phthalocyanine blue derivative color particles, and yellow benzidine derivative color particles.

In a second aspect, an embodiment of the present disclosure further provides a color filter. The color filter comprises a support substrate, a black matrix disposed on the support substrate, and a color filter layer disposed in areas on the support substrate and separated by the black matrix;

wherein the color filter layer is formed by a color photoresist comprising a curable resin, a polyfunctional monomer, an initiator, a solvent, a colorant, and an additive, and the additive is a non-metal catalyst catalyzing a cross-coupling photoreaction to be performed among compounds having a carbon-carbon single bond, compounds having a carbon-oxygen single bond, and compounds having a carbon-nitrogen single bond under ultraviolet light.

In the color filter, wherein a mass percentage of the non-metal catalyst in the color photoresist ranges from 0.1% to 0.2%, and the non-metal catalyst is trifluoroacetic acid.

In a third aspect, an embodiment of the present disclosure further provides a manufacturing method of the above color filter. The method comprises:

S10: coating a black photoresist on the support substrate to form the black matrix; and

S20: forming the color filter layer in the areas on the support substrate and separated by the black matrix to obtain the color filter.

In the manufacturing method of the color filter, wherein the step S20 further comprises:

S201: coating the color photoresist in the areas on the support substrate and separated by the black matrix, wherein the color photoresist comprises a curable resin, a polyfunctional monomer, an initiator, a solvent, a colorant, and an additive, and the additive is a non-metal catalyst catalyzing a cross-coupling photoreaction to be performed among compounds having a carbon-carbon single bond, compounds having a carbon-oxygen single bond, and compounds having a carbon-nitrogen single bond under ultraviolet light;

S202: performing a pre-bake process on the color photoresist;

S203: exposing the color photoresist by a mask and developing to obtain a patterned color filter film; and

S204: performing a hard bake process on the patterned color filter film to cure the patterned color filter film and form the color filter layer, and obtaining the color filter.

In the manufacturing method of the color filter, wherein in the step S201, a mass percentage of the non-metal catalyst in the color photoresist ranges from 0.1% to 0.2%, and the non-metal catalyst is trifluoroacetic acid.

In the manufacturing method of the color filter, wherein the color filter layer comprises a red color filter layer, a blue color filter layer, and a green color filter layer.

Beneficial effect: compared to current technology, the color photoresist, the color filter, and the manufacturing method thereof provided by the present disclosure add a small amount of non-metal catalyst in the color photoresist during the preparation, thereby catalyzing individual positions of the color photoresist to react with a support substrate having silicon nitride material under ultraviolet light, and further improving adhesion between the color photoresist and the support substrate.

### DESCRIPTION OF DRAWINGS

FIG. 1 is a schematic structural diagram of a color filter according to an embodiment of the present disclosure.

FIG. 2 is a flowchart of a manufacturing method of a color filter according to an embodiment of the present disclosure.

FIG. 3 is a schematic structural diagram of a color photoresist and a support substrate under ultraviolet light according to an embodiment of the present disclosure.

FIG. 4 is a schematic diagram of improved adhesion of a color photoresist to a support substrate according to an embodiment of the present disclosure.

### DETAILED DESCRIPTION OF PREFERRED EMBODIMENTS

The present disclosure provides a color photoresist, a color filter, and a manufacturing method thereof. In order to make the purpose, technical solutions, and effects of this disclosure clearer and more definite, the following further describes this disclosure in detail with reference to the drawings and embodiments. It should be understood that the specific embodiments described herein are only used to explain the disclosure, and are not used to limit the disclosure.

Specifically, an embodiment of the present disclosure provides a color photoresist. The color photoresist comprises a curable resin, a polyfunctional monomer, an initiator, a solvent, a colorant, and an additive.

Wherein, the additive is a non-metal catalyst catalyzing a cross-coupling photoreaction to be performed among compounds having a carbon-carbon single bond, compounds having a carbon-oxygen single bond, and compounds having a carbon-nitrogen single bond under ultraviolet light.

Preferably, a mass percentage of the non-metal catalyst in the color photoresist ranges from 0.1% to 0.2%, and the non-metal catalyst is trifluoroacetic acid. The non-metal catalyst is mainly used to catalyze polymers in the color photoresist to form bonds with hydroxyl groups of the support substrate under ultraviolet light, and to improve adhesion of the color photoresist to the support substrate.

Preferably, a mass percentage of the curable resin in the color photoresist ranges from 5% to 8%, and the resin has double bond structures. The curable resin is at least one selected from the group consisting of acrylic resins, epoxy acrylates, polyester acrylates, unsaturated polyesters, polyurethane acrylates, polyether acrylates, and acrylated polyphosphate. The curable resin is preferably an acrylic resin. Wherein, mechanical strength of the color photoresist is controlled by high polymeric molecular weight of the curable resin.

Preferably, a mass percentage of the polyfunctional monomer in the color photoresist ranges from 5% to 8%, and the polyfunctional monomer comprises polyhydroxyl acrylates. Preferably, the polyfunctional monomer comprises at least one of dipentaerythritol pentaacrylate, dipentaerythritol hexaacrylate, aliphatic hexafunctional urethane acrylate polymer, and ethoxylated pentaerythritol tetraacrylate. The polyfunctional monomer is used to form a cross-linked network under ultraviolet light, and shielding the color photoresist from erosion by the developer in subsequent processes.

Preferably, a mass percentage of the initiator in the color photoresist ranges from 0.2% to 0.6%, and the initiator comprises acetophenone derivatives and is used to make the color photoresist generate active free radicals via ultraviolet light.

Preferably, a mass percentage of the solvent in the color photoresist ranges from 70% to 80%. The solvent may be one of propylene glycol methyl ether acetate, ethyl 3-ethoxypropionate, propylene glycol monomethyl ether (PM), and ethylene glycol ethyl ether acetate or mixed solvent thereof, and the solvent in the embodiment of the present disclosure is preferably propylene glycol methyl ether acetate.

Preferably, a mass percentage of the colorant in the color photoresist ranges from 10% to 16%. The colorant is at least one selected from the group consisting of red benzimidazolone derivative color particles, green phthalocyanine green derivative color particles, blue phthalocyanine blue derivative color particles, and yellow benzidine derivative color particles.

In the formula of the color photoresist provided by the embodiment of the present disclosure, a small amount of non-metal catalyst is added, and the non-metal catalyst can catalyze a reaction between the color photoresist and hydroxyl groups of the support substrate to occur in the subsequent processes, thereby improving the adhesion of the color photoresist to the support substrate.

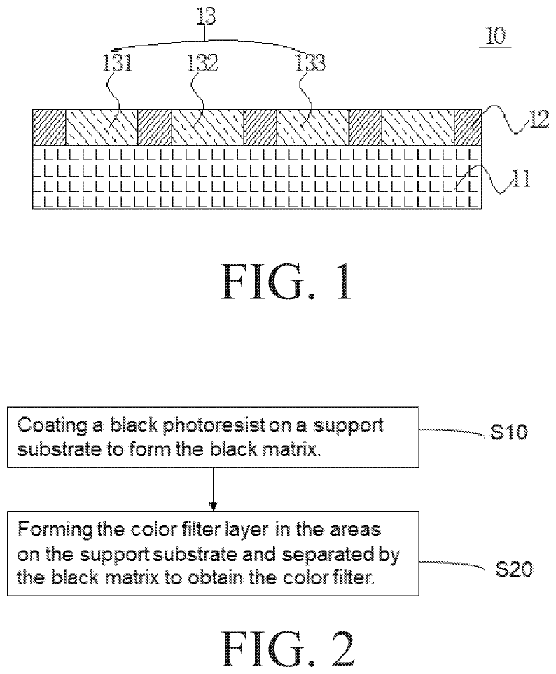

As shown in FIG. 1, an embodiment of the present disclosure further provides a color filter manufactured by the above color photoresist. Wherein, the color filter 10 comprises a support substrate 11, a black matrix 12 disposed on the support substrate 11, and a color filter layer 13 disposed in areas on the support substrate 11 and separated by the black matrix 12.

Wherein, the color filter layer 13 is formed by a color photoresist comprising a curable resin, a polyfunctional monomer, an initiator, a solvent, a colorant, and an additive, and the additive is a non-metal catalyst catalyzing a cross-coupling photoreaction to be performed among compounds having a carbon-carbon single bond, compounds having a carbon-oxygen single bond, and compounds having a carbon-nitrogen single bond under ultraviolet light.

Preferably, a mass percentage of the non-metal catalyst in the color photoresist ranges from 0.1% to 0.2%, and the non-metal catalyst is trifluoroacetic acid. The non-metal catalyst is mainly used to catalyze polymers in the color photoresist to form bonds with hydroxyl groups of the support substrate under ultraviolet light, and to improve adhesion of the color photoresist to the support substrate.

Preferably, a mass percentage of the curable resin in the color photoresist ranges from 5% to 8%, and the resin has double bond structures. The curable resin is at least one selected from the group consisting of acrylic resins, epoxy acrylates, polyester acrylates, unsaturated polyesters, polyurethane acrylates, polyether acrylates, and acrylated polyphosphate. The curable resin is preferably an acrylic resin. Wherein, mechanical strength of the color photoresist is controlled by high polymeric molecular weight of the curable resin.

Preferably, a mass percentage of the polyfunctional monomer in the color photoresist ranges from 5% to 8%, and the polyfunctional monomer comprises polyhydroxyl acrylates. Preferably, the polyfunctional monomer comprises at least one of dipentaerythritol pentaacrylate, dipentaerythritol hexaacrylate, aliphatic hexafunctional urethane acrylate polymer, and ethoxylated pentaerythritol tetraacrylate. The polyfunctional monomer is used to form a cross-linked network under ultraviolet light, and shielding the color photoresist from erosion by the developer in subsequent processes.

Preferably, a mass percentage of the initiator in the color photoresist ranges from 0.2% to 0.6%, and the initiator comprises acetophenone derivatives and is used to make the color photoresist generate active free radicals via ultraviolet light.

Preferably, a mass percentage of the solvent in the color photoresist ranges from 70% to 80%. The solvent may be one of propylene glycol methyl ether acetate, ethyl 3-ethoxypropionate, propylene glycol monomethyl ether (PM), and ethylene glycol ethyl ether acetate or mixed solvent thereof, and the solvent in the embodiment of the present disclosure is preferably propylene glycol methyl ether acetate.

Preferably, a mass percentage of the colorant in the color photoresist ranges from 10% to 16%. The colorant is at least one selected from the group consisting of red benzimidazolone derivative color particles, green phthalocyanine green derivative color particles, blue phthalocyanine blue derivative color particles, and yellow benzidine derivative color particles.

Preferably, the color filter layer 13 comprises a red color filter layer 131, a blue color filter layer 132, and a green color filter layer 133.

The color filter layer 13 provided by the embodiment of the present disclosure uses the color photoresist having a small amount of non-metal catalyst which can catalyze individual groups of the color photoresist to react with hydroxyl groups of the support substrate 11, thereby further improving the adhesion of the color photoresist to the support substrate 11.

As shown in FIG. 2, an embodiment of the present disclosure also provides a manufacturing method of the color filter 10. The method comprises:

S10: coating a black photoresist on the support substrate to form the black matrix.

Specifically, the step S10 further comprises:

providing the support substrate first, wherein, the support substrate is preferably a silicon nitride glass substrate. Then, the support substrate is subjected to cleaning processes, such as extreme ultraviolet radiation and water washing, making a surface of the support substrate has added hydroxyl groups, and causing enhanced hydrophilicity. If the cleaning processes of the support substrate, such as extreme ultraviolet radiation and water washing, are omitted, the problem of color photoresist residues easily occurs in subsequent processes. Then, the black photoresist is coated on the support substrate to form the black matrix.

S20: forming the color filter layer in the areas on the support substrate and separated by the black matrix to obtain the color filter.

Specifically, the step S20 comprises:

preparing a color photoresist solution of the color photoresist, wherein the color photoresist comprises a curable resin, a polyfunctional monomer, an initiator, a solvent, a colorant, and an additive, and the additive is a non-metal catalyst catalyzing a cross-coupling photoreaction to be performed among compounds having a carbon-carbon single bond, compounds having a carbon-oxygen single bond, and compounds having a carbon-nitrogen single bond under ultraviolet light.

Then performing a pre-bake process on the color photoresist. Wherein, a temperature of the pre-bake process ranges from 20° C. to 50° C., and time for the pre-bake process ranges from 30 seconds to 120 seconds.

Then exposing the color photoresist by a mask and developing to obtain a patterned color filter film, and then performing a hard bake process on the patterned color filter film to cure the patterned color filter film and form the color filter layer, and obtaining the color filter.

Wherein, a temperature of the hard bake process ranges from 20° C. to 100° C., and time for the hard bake process ranges from 5 minutes to 30 minutes.

Preferably, a mass percentage of the non-metal catalyst in the color photoresist ranges from 0.1% to 0.2%, and the non-metal catalyst is trifluoroacetic acid, wherein a small amount of trifluoroacetic acid is dissolved in a solvent of water/acetone (9:2) and is added to a preparing photoresist solution. The non-metal catalyst is mainly used to catalyze polymers in the color photoresist to form bonds with hydroxyl groups of the support substrate under ultraviolet light, and to improve adhesion of the color photoresist to the support substrate.

Preferably, a mass percentage of the curable resin in the color photoresist ranges from 5% to 8%, and the resin has double bond structures. The curable resin is at least one selected from the group consisting of acrylic resins, epoxy acrylates, polyester acrylates, unsaturated polyesters, polyurethane acrylates, polyether acrylates, and acrylated polyphosphate. The curable resin is preferably an acrylic resin. Wherein, mechanical strength of the color photoresist is controlled by high polymeric molecular weight of the curable resin.

Preferably, a mass percentage of the polyfunctional monomer in the color photoresist ranges from 5% to 8%, and the polyfunctional monomer comprises polyhydroxyl acrylates. Preferably, the polyfunctional monomer comprises at least one of dipentaerythritol pentaacrylate, dipentaerythritol hexaacrylate, aliphatic hexafunctional urethane acrylate polymer, and ethoxylated pentaerythritol tetraacrylate. The polyfunctional monomer is used to form a cross-linked network under ultraviolet light, and shielding the color photoresist from erosion by the developer in subsequent processes.

Preferably, a mass percentage of the initiator in the color photoresist ranges from 0.2% to 0.6%, and the initiator comprises acetophenone derivatives and is used to make the color photoresist generate active free radicals via ultraviolet light.

Preferably, a mass percentage of the solvent in the color photoresist ranges from 70% to 80%. The solvent may be one of propylene glycol methyl ether acetate, ethyl 3-ethoxypropionate, propylene glycol monomethyl ether (PM), and ethylene glycol ethyl ether acetate or mixed solvent thereof, and the solvent in the embodiment of the present disclosure is preferably propylene glycol methyl ether acetate.

Preferably, a mass percentage of the colorant in the color photoresist ranges from 10% to 16%. The colorant is at least one selected from the group consisting of red benzimidazolone derivative color particles, green phthalocyanine green derivative color particles, blue phthalocyanine blue derivative color particles, and yellow benzidine derivative color particles.

Preferably, the color filter layer comprises a red color filter layer, a blue color filter layer, and a green color filter layer.

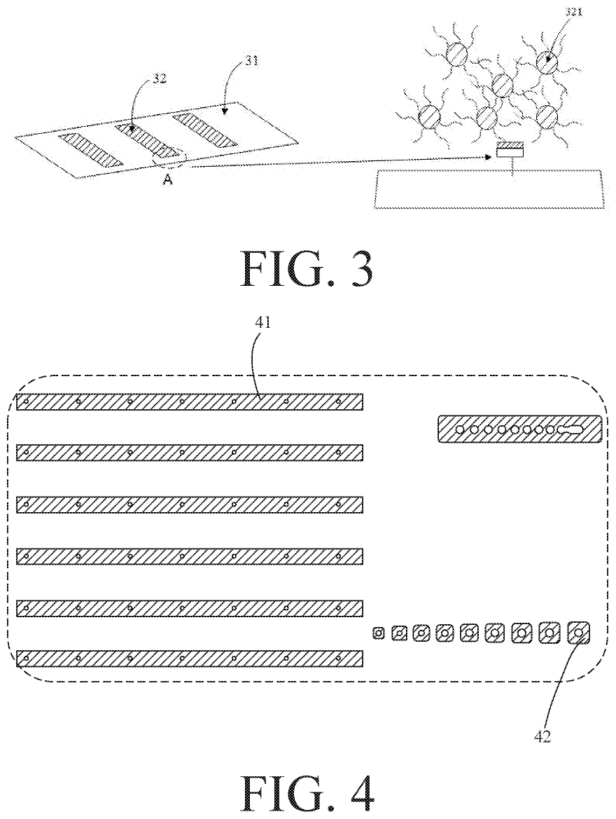

As shown in FIG. 3, FIG. 3 is a schematic structural diagram of a color photoresist and a support substrate under ultraviolet light according to an embodiment of the present disclosure. Wherein, a color photoresist 32 is coated on a support substrate 31 and is exposed to ultraviolet light to form a patterned color filter film. Wherein, the support substrate 31 is a silicon nitride glass substrate. The support substrate 31 would be subjected to pre-cleaning processes: to remove organic pollutants by extreme ultraviolet radiation and to remove tiny particles on a surface of the support substrate 31 by water washing, and then hydroxyl groups on the surface of the support substrate 31 are increased.

Wherein, the right side of FIG. 3 is an enlarged schematic view of the left side A of FIG. 3. Specifically, in the step of exposing the color photoresist 32 by ultraviolet light to form the patterned color filter film, a small amount of the non-metal catalyst (trifluoroacetic acid is preferred, and a mass percentage of the non-metal catalyst in the color photoresist ranges from 0.1% to 0.2%.) in a part of the color photoresist 32 exposed by the ultraviolet light plays a catalytic role to catalyze oxygen-containing groups of a part of organic polymer molecules 321 in the color photoresist 32 to react with hydroxyl groups of the support substrate 31 to form bonds, thereby forming polymeric ether compounds, and then the color filter film is obtained.

Specifically, a chemical reaction equation of a part of organic polymer molecules 321 in the color photoresist 32 and organics having hydroxyl groups of the support substrate 31 under catalyzing of the non-metal catalyst (trifluoroacetic acid is preferred, and a mass percentage of the non-metal catalyst in the color photoresist ranges from 0.1% to 0.2%.) at 15° C. and under ultraviolet light is as follows:

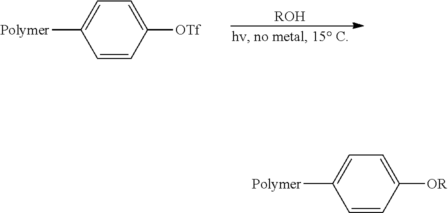

Specifically, substituent side chains of the polymer in the color photoresist 32 are trifluoromethanesulfonyl groups (-Tf). Wherein, the ROH refers to organics having hydroxyl groups on a surface of the support substrate 31 (a silicon nitride glass substrate), and the R group is a free substituent of the surface of the support substrate 31 bonding to a hydroxyl group.

Since the non-metal catalyst has a low catalytic efficiency when compared to transition metal catalysts, only individual positions (a part of organic polymer molecules 321) having strong reactivity are reacted, which improves the adhesion without causing excessive problems of color photoresist residues. Transition metal catalysts are sensitive to water and oxygen, and easily have metal residues, thereby unsuitable for application of commercial production. The non-metal catalyst solves the above metal related problems and is suitable for commercial application of color photoresists.

As shown in FIG. 4, FIG. 4 is a schematic diagram of improved adhesion of a color photoresist 42 to a support substrate 41 according to an embodiment of the present disclosure. It can be known from the figure, a small amount of non-metal catalyst added in the formula of the color photoresist 42 can effectively improve the poor adhesion of the color photoresist 42 to the support substrate 41.

In summary, the color photoresist, the color filter, and the manufacturing method thereof provided by the embodiment of the present disclosure add a small amount of non-metal catalyst in the color photoresist during the preparation, thereby catalyzing individual positions of the color photoresist to react with a support substrate having silicon nitride material under ultraviolet light, and further improving adhesion between the color photoresist and the support substrate.

It can be understood that for a person of ordinary skill in the art, equivalent replacements or changes can be made according to the technical solution of the present disclosure and its inventive concept, and all these changes or replacements should fall within the protection scope of the claims attached to the present disclosure.

What is claimed is:

1. A color photoresist, comprising a curable resin, a polyfunctional monomer, an initiator, a solvent, a colorant, and an additive;
wherein the additive is a non-metal catalyst catalyzing a cross-coupling photoreaction to be performed among compounds having a carbon-carbon single bond, compounds having a carbon-oxygen single bond, and compounds having a carbon-nitrogen single bond under ultraviolet light.

2. The color photoresist according to claim 1, wherein a mass percentage of the non-metal catalyst in the color photoresist ranges from 0.1% to 0.2%, and the non-metal catalyst is trifluoroacetic acid.

3. The color photoresist according to claim 2, wherein a mass percentage of the curable resin in the color photoresist ranges from 5% to 8%, a mass percentage of the polyfunctional monomer in the color photoresist ranges from 5% to 8%, a mass percentage of the initiator in the color photoresist ranges from 0.2% to 0.6%, a mass percentage of the solvent in the color photoresist ranges from 70% to 80%, and a mass percentage of the colorant in the color photoresist ranges from 10% to 16%.

4. The color photoresist according to claim 3, wherein the curable resin comprises an acrylic resin, the polyfunctional monomer comprises polyhydroxyl acrylate, the initiator comprises an acetophenone derivative, the solvent comprises propylene glycol methyl ether acetate, and the colorant is at least one selected from the group consisting of red benzimidazolone derivative color particles, green phthalocyanine green derivative color particles, blue phthalocyanine blue derivative color particles, and yellow benzidine derivative color particles.

5. A color filter, comprising a support substrate, a black matrix disposed on the support substrate, and a color filter layer disposed in areas on the support substrate and separated by the black matrix;
wherein the color filter layer is formed by a color photoresist comprising a curable resin, a polyfunctional monomer, an initiator, a solvent, a colorant, and an additive, and the additive is a non-metal catalyst catalyzing a cross-coupling photoreaction to be performed among compounds having a carbon-carbon single bond, compounds having a carbon-oxygen single bond, and compounds having a carbon-nitrogen single bond under ultraviolet light.

6. The color filter according to claim 5, wherein a mass percentage of the non-metal catalyst in the color photoresist ranges from 0.1% to 0.2%, and the non-metal catalyst is trifluoroacetic acid.

7. A manufacturing method of the color filter according to claim 5, comprising:
S10: coating a black photoresist on the support substrate to form the black matrix; and
S20: forming the color filter layer in the areas on the support substrate and separated by the black matrix to obtain the color filter.

8. The manufacturing method of the color filter according to claim 7, wherein the step S20 comprises:
S201: coating the color photoresist in the areas on the support substrate and separated by the black matrix, wherein the color photoresist comprises a curable resin, a polyfunctional monomer, an initiator, a solvent, a colorant, and an additive, and the additive is a non-metal catalyst catalyzing a cross-coupling photoreaction to be performed among compounds having a carbon-carbon single bond, compounds having a carbon-oxygen single bond, and compounds having a carbon-nitrogen single bond under ultraviolet light;
S202: performing a pre-bake process on the color photoresist;
S203: exposing the color photoresist by a mask and developing to obtain a patterned color filter film; and
S204: performing a hard bake process on the patterned color filter film to cure the patterned color filter film and form the color filter layer, and obtaining the color filter.

9. The manufacturing method of the color filter according to claim 8, wherein in the step S201, a mass percentage of the non-metal catalyst in the color photoresist ranges from 0.1% to 0.2%, and the non-metal catalyst is trifluoroacetic acid.

10. The manufacturing method of the color filter according to claim 8, wherein the color filter layer comprises a red color filter layer, a blue color filter layer, and a green color filter layer.
